(19) United States
(12) Patent Application Publication
(10) Pub. No.: US 2006/0191864 A1
(43) Pub. Date: Aug. 31, 2006

(54) Mask, mask manufacturing method, pattern forming apparatus, and pattern formation method

(75) Inventor: Shinichi Yotsuya, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/362,579

(22) Filed: Feb. 24, 2006

(30) Foreign Application Priority Data
Feb. 25, 2005 (JP) 2005-050337

(51) Int. Cl. B05D 5/12; C23F 1/00

(52) U.S. Cl. 216/41; 427/127; 427/443.1; 427/256; 118/213; 216/22

(57) ABSTRACT

A mask for forming a thin film having a first pattern against a film formation substrate, including: a nonmagnetic substrate having an aperture corresponding to the first pattern; and a magnetic film having a second pattern and arranged on the nonmagnetic substrate.

### BACKGROUND

1. Technical Field

The present invention relates to a mask, a mask manufacturing method, a pattern forming apparatus, and a pattern formation method.

2. Related Art

Since an organic electroluminescence (hereinafter referred to as organic EL) device is equipped with a spontaneously light-emitting, high-speed-response display element having a thin film lamination structure, it can form a lightweight display panel excellent for a moving image. Much attention is currently focused on such an organic EL device used as a display panel for a flat panel display (FPD) television and the like.

A typically known manufacturing method therefor is a method that includes patterning a transparent anode such as indium tin oxide (ITO) so as to have a desired form, laminating organic materials on the transparent anode using a vapor deposition method, and forming a cathode thereafter.

Manufacture of a full-color organic EL device, in particular, requires forming a pattern by depositing an organic material of each of the colors R, G, and B via a mask. In such a mask deposition method, there is a technique using a metal mask for the mask. In this technique, vapor deposition is carried out in a situation that a film formation substrate and the metal mask are attached to each other by a permanent magnet placed on the other side of the film formation substrate.

Now, when the size of the panel increases, a larger metal mask needs to be formed. However, it is very difficult to produce a thin, large, high-precision metal mask. Also, because the thermal expansion coefficient of the metal mask is much larger than that of the film formation substrate such as glass, the metal mask becomes larger in size than the film formation substrate due to the radiant heat at the time of the vapor deposition. Thus, the closely attached metal mask and the film formation substrate become misaligned, and a size error takes place at the deposition portion. Moreover, when manufacturing a large panel, the error becomes greater as the errors accumulate, and, thus, it is said that the panel that can be manufactured by the mask deposition is a small to medium size panel having no more than 20 inches at the maximum.

Recently, there has been developed a technique in which the mask is manufactured using a silicon substrate. However, as the size of the silicon mask increases, the silicon mask flexes by its own weight, and, even if the silicon mask and a film deposition substrate are precisely aligned, an unnecessary gap is created between the silicon mask and the film deposition substrate. Thus, it is difficult to obtain a large and highly precise organic EL panel.

In order to solve these problems, JP-A-2002-317263 proposes a method in which a vapor deposition process is carried out by vertically arranging the silicon mask and a film deposition substrate.

Further, JP-A-2002-47560 proposes a method in which the flexure of a silicon mask by its own weight can be prevented by forming a magnetic film on the entire surface of one surface of a silicon mask and attracting this magnetic film by magnetic force.

However,. the former technique has not been put into practical use, since it is faced with difficulties in transporting the silicon mask and the film deposition substrate, removing the silicon mask, and conducting the vapor deposition method in a lateral direction.

In the latter technique, also, when the magnetic film is formed on the entire surface of one surface of the silicon mask, the flexure increases further by the weight of the magnetic film, and the pattern portion deforms (bends) due to the influence of the internal stress (film stress) of the magnetic film.

Thus, in the conventional techniques, there is a problem that it is difficult to prevent the flexure of the large-size silicon mask caused by its own weight.

### SUMMARY

An advantage of the present invention is to provide a mask that can prevent the flexure of the large-size silicon mask caused by its own weight, a method for manufacturing the mask, a pattern forming apparatus using the mask, and a pattern formation method therefor.

The mask, the mask manufacturing method, the pattern forming apparatus, and the pattern formation method of the invention adopt the following measures:

According to a, first aspect of the invention, a mask for forming a thin film having a first pattern against a film formation substrate includes: a nonmagnetic substrate having an aperture corresponding to the first pattern; and a magnetic film having a second pattern and arranged on the nonmagnetic substrate.

In this case, by attracting the magnetic film on the nonmagnetic substrate to the film formation substrate by a magnetic force, the mask may be prevented from being fluxed by its own weight. Further, because the magnetic film having the second pattern is arranged on the nonmagnetic substrate, the bending and the like of the nonmagnetic substrate due to the internal stress of the magnetic film may be prevented.

It is preferable that the magnetic film is arranged on a surface of the nonmagnetic substrate opposite from the film formation substrate. Consequently, the magnetic film may be readily attracted (attached) to the film formation substrate by the magnetic force.

Further, it is preferable that the magnetic film is arranged in a central region of the opposite substrate. Accordingly, the central region where the flexure of the magnetic film by its own weight becomes great may be attracted (attached) well towards the film formation substrate.

Furthermore, it is preferable that the magnetic film has a thickness of from 0.5 μm to 5.0 μm. Accordingly, the occurrence of the flexure due to the weight of the magnetic film may be prevented, and the distance between the mask and the film formation substrate may be kept short.

According to a second aspect of the invention, a mask manufacturing method for forming a thin film having a first pattern against a film formation substrate includes: forming an aperture corresponding to the first pattern against a nonmagnetic substrate; and arranging a magnetic film having a second pattern on the nonmagnetic substrate.

In this case, because the magnetic film is arranged on the nonmagnetic substrate, the flexure of the enlarged mask by its own weight may be prevented by attracting (attaching) the magnetic film towards the film formation substrate by a magnetic force. Also, because the magnetic film having the second pattern is arranged on the nonmagnetic substrate, the bending and the like of the nonmagnetic substrate due to the internal stress of the magnetic film may be prevented.

Moreover, it is preferable that the magnetic film arrangement process includes: first forming a base metal film corresponding to the second pattern on the predetermined surface; and secondly forming the magnetic film on the base metal film. By disposing the base metal film, the magnetic film may be readily formed so as to have a predetermined thickness on the base metal film.

Further, it is preferable that the second magnetic film formation process includes depositing the magnetic film on the base metal film by an electroless plating method. Consequently, the thickness of the magnetic film may be readily controlled.

According to a third aspect of the invention, a pattern forming apparatus includes: support portions supporting the mask and the film formation substrate of the first aspect of the invention from opposite directions in a manner that the film formation substrate comes vertically above the mask; a magnetic attraction portion which is arranged vertically above the film formation substrate and which applies a magnetic attraction force to the mask to attract the mask towards the film formation substrate; and a film formation portion at which a thin film formation material is applied to the film formation substrate via the mask.

In this case, even if the size of the mask increases, the mask may be well attached to the film formation substrate, and the first pattern may be precisely formed on the film formation substrate.

According to a fourth aspect of the invention, a pattern formation method includes: arranging the mask and the film formation substrate of the first aspect of the invention so that they oppose each other and that the film formation substrate comes vertically above the mask; applying a magnetic attraction force to the mask to attract the mask towards the film formation substrate; and applying a thin film formation material to the film formation substrate via the mask.

In this case, even if the size of the mask increases, the mask can be well attached to the film formation substrate, and the first pattern can be precisely formed on the film formation substrate.

### BRIEF DESCRIPTION OF THE DRAWINGS

The invention will be described with reference to the accompanying drawings, wherein like numbers reference like elements.

FIGS. 1A and 1B are diagrams to explain a structure of a mask M.

FIGS. 2A and 2B are diagrams showing exemplary configurations of a pattern of a magnetic film 28.

FIGS. 3A through 3C are diagrams showing a method for manufacturing the mask M in order of the manufacturing processes.

FIGS. 4A through 4C are diagrams showing the processes following FIG. 3C.

FIGS. 5A through 5C are diagrams showing the processes following FIG. 4C.

FIGS. 6A and 6B are tables showing plating bath compositions and bath conditions.

FIG. 7 is a pattern diagram of a vapor deposition apparatus 50.

FIGS. 8A through 8C are diagrams showing a method for manufacturing an organic EL device DP in order of the manufacturing processes.

FIGS. 9A through 9C are diagrams showing electronic apparatuses.

### DESCRIPTION OF EXEMPLARY EMBODIMENTS

Embodiments of the mask, the mask manufacturing method, the pattern forming apparatus, and the pattern formation method of the invention will now be described with reference to the drawings. The scale sizes of the layers and members differ in each drawing so that they are recognizable in each drawing.

Mask

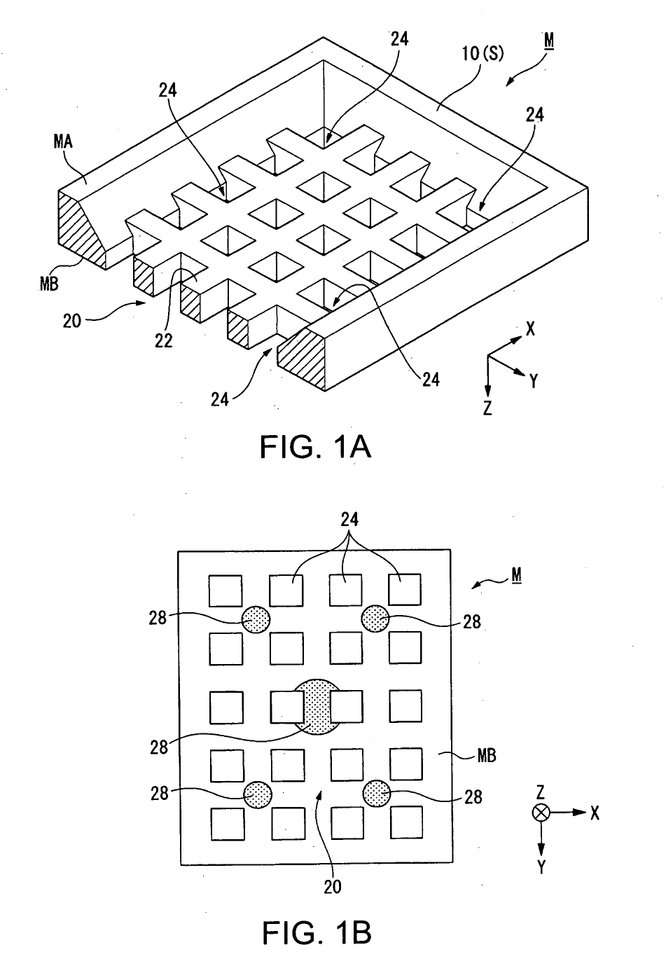

FIGS. 1A and 1B are diagrams to explain the structure of the mask of the first aspect of the invention. FIG. 1A is a cross-sectional perspective diagram of the mask, and FIG. 1B is a diagram showing the rear surface of the mask.

A mask M is composed of a frame 10 outlining the mask M and a pattern portion 20 having a plurality of mask apertures 24 disposed on the inner side of the frame 10. Further, the frame 10 is formed using the whole thickness of the silicon wafer.

The pattern portion 20 is composed of a plurality of beams 22 linked to the frame 10 and extending in X and Y directions and of the plurality of mask apertures 24 that are made by the plurality of beams 22 surrounding the apertures. That is, since the beams are in a net-like structure, the plurality of mask apertures 24 are arranged in matrix. Additionally, the pattern portion 20 is not limited to the structure having the plurality of uniformly-pitched mask apertures 24 arranged in matrix but can be suitably modified corresponding to the pattern formed on a film-forming object.

Moreover, as shown in FIG. 1B, a magnetic film 28, which is made by forming a magnetic body into a film in a predetermined pattern, is formed on a rear surface MB of the mask M. The rear surface MB of the mask M is a surface facing the film-forming object (the film formation substrate) when forming films by vapor deposition, sputtering, and the like, and is a surface facing a side of the film-forming object to which material gases and atoms of thin-film forming particles reach.

The magnetic film 28 prevents the gap between the film-forming object and the mask M created when the pattern portion 20, particularly the central region thereof, is flexed when the mask M is disposed in the film formation apparatus and overlapped with the film-forming object. That is, the magnetic film 28 is used to suppress the flexure in the pattern portion 20 of the mask M and to attach the mask M to the film-forming object in such a manner that the magnetic film 28 formed on the rear surface MB of the mask M is attracted upwards (upwards the gravitational force) by the magnetic force. As for the magnetic force that attracts the magnetic film 28 upwards will be described hereinafter.

The magnetic film 28 is a film formed using a ferromagnetic body containing Ni, Fe, and Co. More specifically, for the magnetic film 28, a Ni—Fe—P film or a Co—Ni—P film can be used. These materials compose the magnetic film 28, as they are readily formed into a film on the rear surface MB of the mask M by the electroless plating method.

Preferably, the thickness of the magnetic film 28 is 0.3 μm or more and 5.0 μm or less and is substantially uniform. If the thickness of the magnetic film 28 is 0.3 μm or less, there is not enough magnetic force to attract the magnetic film 28 upwards, and the situation in which the gap is formed between the mask M and the film-forming object may not be resolved.

In contrast, if the thickness of the magnetic film 28 is 5.0 μm or more, the weight of the magnetic film 28 will be so great that it further creates a gap between the mask M and the film-forming object. Further, if the distance between the mask M and the film-forming object becomes large due to the presence of the magnetic film 28, an area on the film-forming object, to which the thin-film forming particles reach and are applied via the mask apertures 24 of the pattern portion 20, expands, and it becomes difficult to form a high-precision pattern.

The magnetic film 28 is made to have the uniform thickness in order to maintain a fixed distance between the body of the mask M and the film-forming object and to form a substantially uniform pattern on the film-forming object.

Further, the reason for forming the magnetic film 28 in a predetermined pattern instead of forming the same on the entire surface of its rear surface MB is to prevent the bending of the mask M. That is, the pattern portion 20 of the mask M is formed as thinly as possible so that the thin-film forming particles that pass through the mask apertures 24 of the pattern portion 20 can readily reach to the film-forming object during the formation of the thin film on the film-forming object using the film formation apparatus. Thus, if the magnetic film 28 is formed on the entire surface of the rear surface MB, the pattern portion 20 deforms (bends) as it is affected by the internal stress (the film stress) of the magnetic film 28.

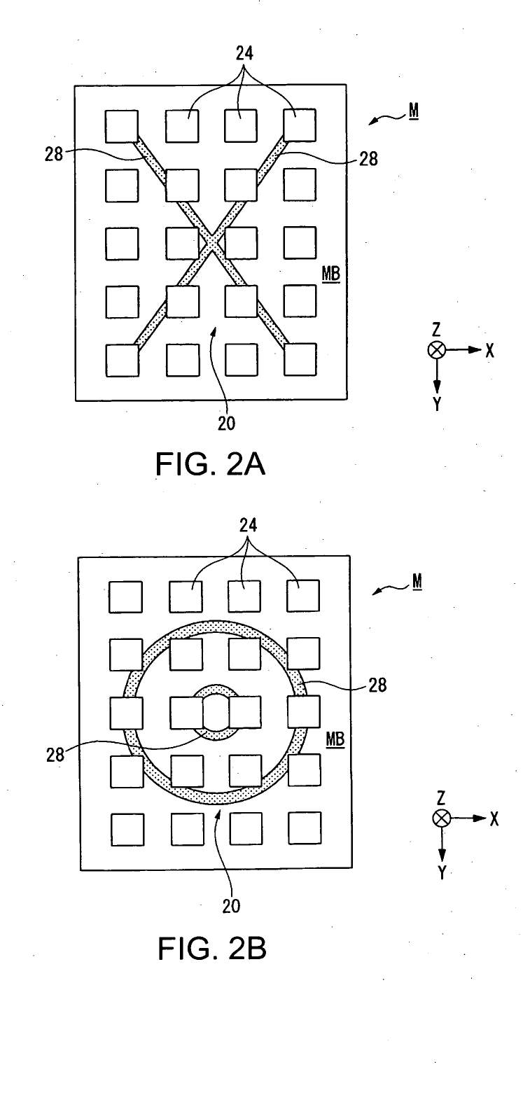

Therefore, in order to avoid these undesirable situations, the magnetic film 28 is formed on the rear surface MB in such a way that the flexure by the weight of the pattern portion 20 of the mask M itself can be successfully suppressed. For example, as FIG. 1B shows, a plurality of magnetic films 28 are arranged in a distributed manner at the central region and at an area surrounding the central region of the pattern portion 20 where the flexure by its own weight is great. Alternatively, for example, the magnetic films 28 may be arranged in a cross pattern as shown in FIG. 2A or in a multiple circular pattern as shown in FIG. 2B.

The pattern of these magnetic films 28 is mainly arranged at the central region of the pattern portion 20. Further, it is preferable that the pattern of these magnetic films 28 is symmetrical around the central region. This is because the central region of the pattern portion 20 that flexes by its own weight can be reliably attracted upwards by arranging the magnetic films 28 mainly at the central region. Also, by forming the magnetic films 28 in the pattern symmetrical around the central region, the pattern portion 20 can be evenly attracted upwards, and, thereby, the deformation of the pattern portion 20 caused by an uneven attraction can be avoided.

Additionally, although it is possible to form the magnetic film 28 on a front surface (surfacing downwards the gravitational force) of the mask M, a large magnetic force is required in order to attract this magnetic film 28 upwards. Further, although it is also possible to form the magnetic film 28 on both surfaces, it should be noted that the magnetic film 28 may become so heavy that it may flex by its own weight.

With the mask M of the present embodiment as thus described, because the magnetic film 28 is arranged on the rear surface MB of the mask M, the mask M can be attached to the film-forming object by attracting this magnetic film 28 upwards using the magnetic force. That is, even if the size of the mask M increases, the flexure of the pattern portion 20 by its own weight can be prevented.

Further, since the magnetic film 28 is formed so as to have the predetermined pattern, the deformation of the pattern portion 20 by the internal stress (the film stress) of the magnetic film 28 can be avoided.

Moreover, it is possible to magnetize the magnetic film 28 before using the same. Furthermore, in substitution for the magnetic film 28, a permanent magnetic material may be disposed on the rear surface MB of the mask M.

Mask Manufacturing Method

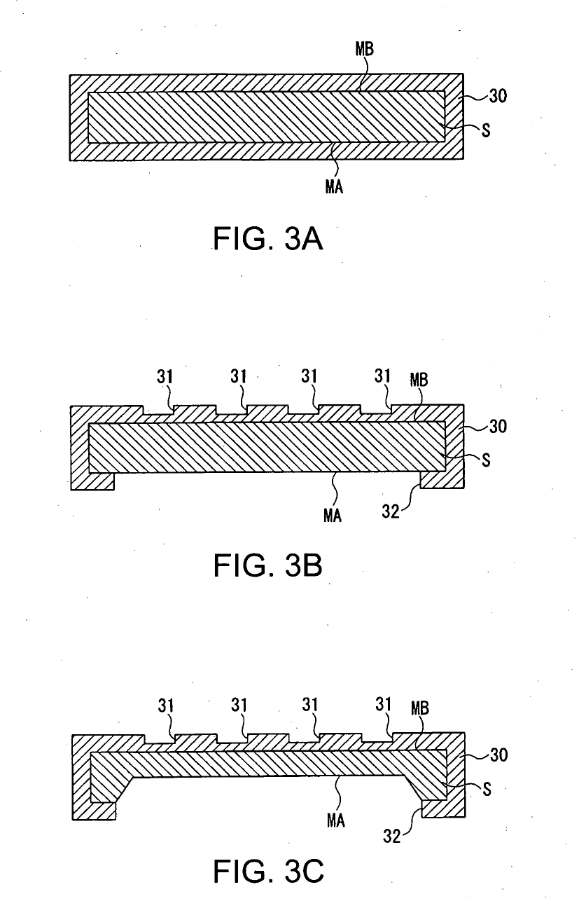

The method for manufacturing the mask M will now be described with reference to FIGS. 3 through FIGS. 5. FIGS. 3 through FIGS. 5 show cross-sectional pattern diagrams of the mask M.

First, as shown in FIG. 3A, a silicon substrate S undergoes a thermal oxidation process so as to form an etching-resistant film 30 made of silicon oxide.

The etching-resistant film 30 is a film having resistivity to a crystal anisotropic etching solution (e.g., an aqueous solution of tetramethylammonium hydroxide or the like) as will be described hereinafter. Instead of the silicon oxide film formed by the mentioned thermal oxidation, the etching-resistant film 30 may be a silicon oxide film, silicon nitride film, or a silicon carbide film formed by a CVD method, or an Au- or Pt-sputtered film, for example.

The etching-resistant film 30 is a silicon oxide film formed by carrying out the thermal oxidation process. Further, the thickness of this silicon oxide film 30 is preferably about 1 μm.

Next, as shown in FIG. 3B, a plurality of dented portions 31 are formed at portions on one main surface (the rear surface MB) of the etching-resistant film 30 formed on the surface of the silicon substrate S. An alignment pattern of these dented portions 31 corresponds to the alignment pattern of the mask apertures 24 to be formed. Further, the dented portions 31 do not penetrate through the etching-resistant film 30 to reach the surface of the silicon substrate S but are formed in a manner that the silicon oxide thin film remains at the bottom portion.

Further, when forming the dented portions 31, a front-side opening portion 32 is also formed by partially removing the etching-resistant film 30 that is formed on another main surface (a front surface MA) opposite from the one main surface (the rear surface MB) having the dented portions 31. The front-side opening portion 32 has a structure in that the plurality of front-side dented portions 31 are enclosed in the opening when seen in a plan view. Additionally, these processes of forming the dented portions and forming the opening portion are carried out by photolithography and etching techniques.

Then, as shown in FIG. 3C, the silicon substrate S is etched using the etching-resistant film 30 as the mask. In this case, the front surface MA of the silicon substrate S is made into a thin film by a silicon crystal anisotropic etching via the front-side opening portion 32 of the etching-resistant film 30.

More specifically, the anisotropic etching is conducted by immersing the silicon substrate S having the etching-resistant film 30 as the mask in the aqueous solution of tetramethylammonium hydroxide for a predetermined period of time.

Since this etching solution is an organoalkali solution and does not use potassium or sodium, it is considered that the solution does not contaminate the silicon substrate and can prevent the film-forming object (the film formation substrate) from being contaminated by potassium and sodium during the film formation process such as the vapor deposition.

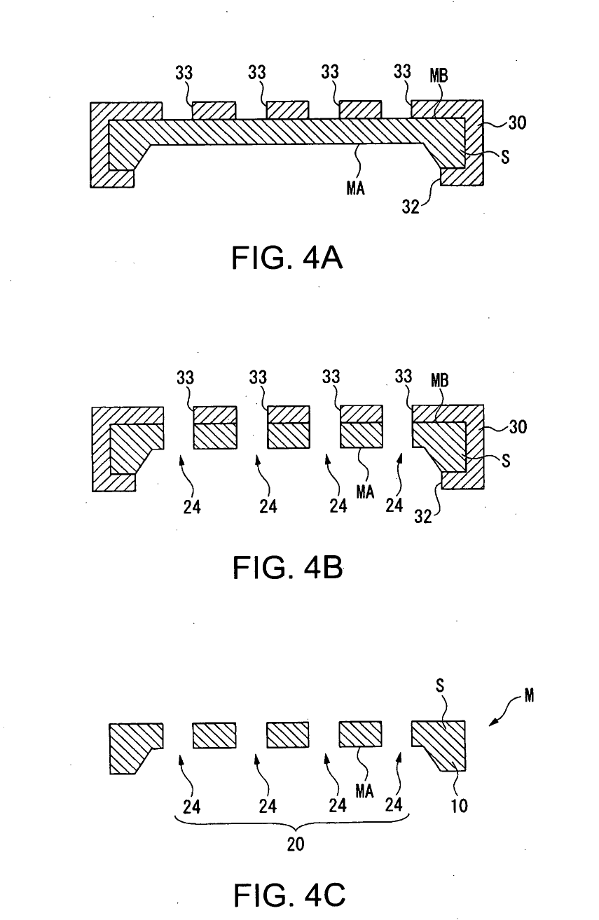

Next, as shown in FIG. 4A, after thinning down the silicon substrate S up to a thickness of about 70 μm by the referenced anisotropic etching, the whole etching-resistant film 30 is made even thinner by etching so that the silicon substrate S is exposed at the dented portions 31 of the etching-resistant film 30. As a result, in addition to the front-side opening portion 32, rear-side opening portions 33 are formed in a predetermined pattern in the etching-resistant film 30.

Thereafter, as shown in FIG. 4B, the mask apertures 24, which have the pattern corresponding to the pattern of the rear-side opening portions 33 formed in the etching-resistant film 30, are formed by dry etching using the etching-resistant film 30 as the mask. The dry etching method employed here is Deep-RIE used in a technology of micro electro mechanical systems (MEMS). Further, the etching for forming these mask apertures 24 may be a time-modulated plasma etching (a method in which formation and etching of a side wall protective film are alternately conducted).

Then, as shown in FIG. 4C, by peeling off the etching-resistant film 30, the frame 10 and the pattern portion 20 are completed.

Next, the magnetic film 28 is formed on the rear surface MB of the mask M.

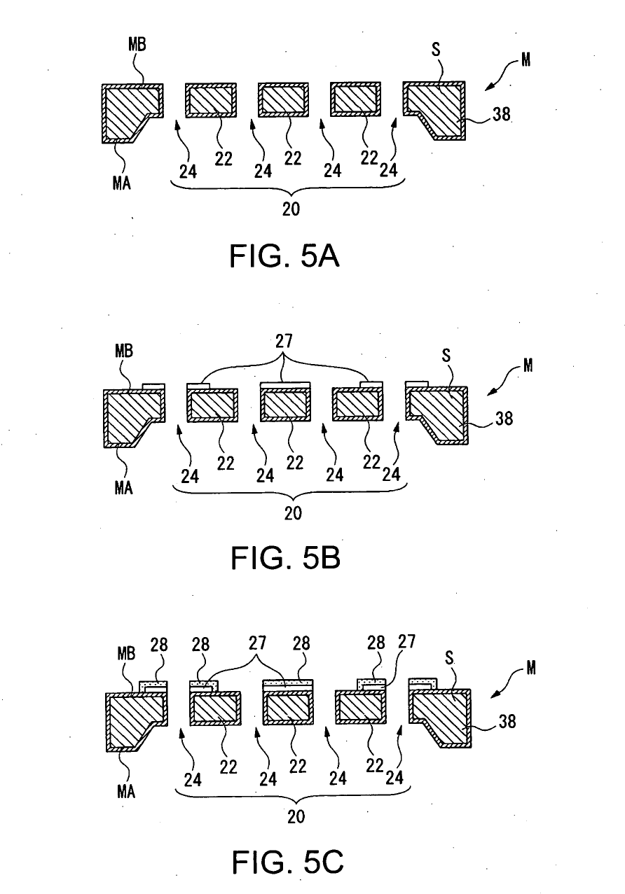

At first, as shown in FIG. 5A, an alkali-resistant film 38 is formed again on the mask M. The alkali-resistant film 38 is a film having resistivity against an alkali solution used in a process such as a zincate treatment or an electroless plating and is formed in order to prevent the mask M (silicon) from dissolving when immersed in the alkali solution.

The alkali-resistant film 38 is a silicon oxide film formed by the thermal oxidation process and is preferably an extremely thin oxide film having a thickness of between about 0.015 μm and 0.05 μm.

Next, as shown in FIG. 5B, a base film 27 made of an alloy film having a desired pattern at the pattern portion 20 is formed on the rear surface MB of the mask M by a mask sputtering method. The base film 27 is a film that becomes the base on which the magnetic film 28 is deposited in the electroless plating process that follows hereafter.

For the base film 27, it is preferable to use a Ni alloy or a Cu alloy. Further, the thickness of the base film 27 is preferably about 0.3 μm. That is, it can be any alloy film that enables the deposition of the magnetic film 28.

Then, as shown in FIG. 5C, the magnetic film 28 is formed on the base film 27 using the electroless plating method.

Since the electroless plating method does not require electric current to flow to the base film 27, the magnetic film 28 can be readily laminated on the base film 27. In particular, the magnetic film 28 can be laminated even when the base film 27 has a pattern arranged in a distributed manner at a plurality of spots. Therefore, by immersing the mask M in the alkali solution, the magnetic film 28 can be readily formed on the rear surface MB of the mask M.

Further, since only at a selected portion on the rear surface MB of the mask M, that is, only on the base film 27, is the magnetic film 28 deposited (laminated), the materials are not wasted, and the manufacturing cost can be reduced. Moreover, it is further advantageous that the stress of the film (the film stress) to be deposited can be controlled by use of additives.

The magnetic film 28 is the film made of the ferromagnetic body containing Ni, Fe, Co, or the like. More specifically, the magnetic film 28 is a Ni—Fe—P film, a Co—Ni—P film, or the like.

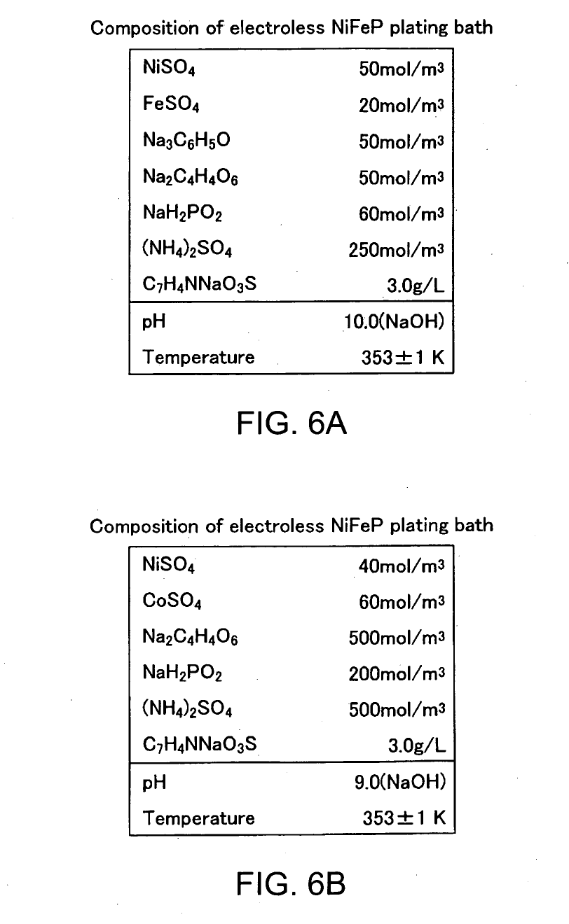

When forming the Ni—Fe—P film, a Cu film is used for the base film 27. Further, as for plating bath compositions and conditions, a plating bath containing about 7-8 atomic % of Fe against Ni is used as shown in FIG. 6A. Consequently, the formed magnetic film 28 shows properties of a very soft ferromagnetic permalloy film.

Further, saccharin (C₇H₄NNaO₃S) is added this plating bath as a stress relaxation agent so as to control the internal stress (the film stress) of the magnetic film 28 to be very weak. Furthermore, pH of the plating bath is adjusted by using sodium hydroxide.

Moreover, if the Co—Ni—P film is used for the magnetic film 28, a Ni film is used for the base film 27. Also, as for the plating bath compositions and conditions, those shown in FIG. 6B are employed. Further, pH of the plating bath is adjusted by using ammonia water.

By these processes, the frame 10 and the pattern portion 20 are formed from the silicon substrate S, and, further, the mask M having the magnetic film 28 having the predetermined pattern on its rear surface MB is completed.

In addition, the alkali-resistant film 38 is the extremely thin oxide film that does not influence negatively on the functions of the mask M, and, thus, does not necessarily need peeling off.

Vapor Deposition Apparatus and Vapor Deposition Method

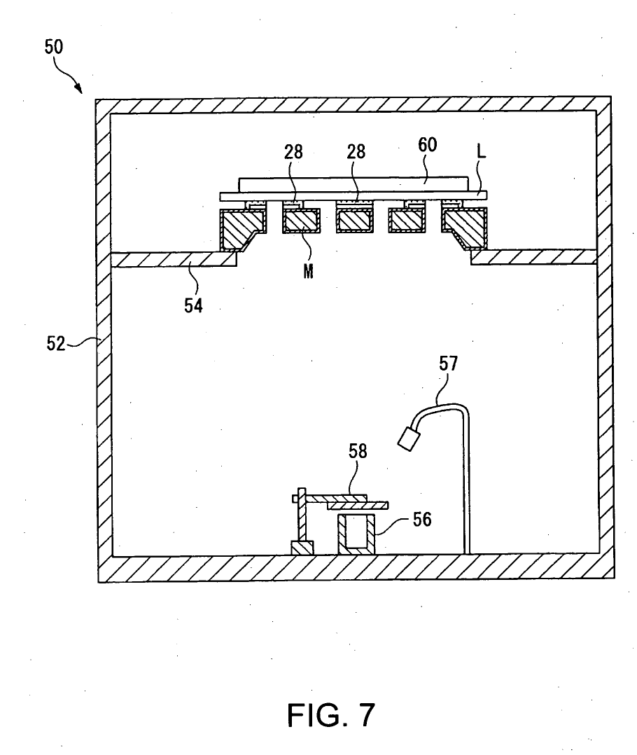

Now, the vapor deposition apparatus and the vapor deposition method utilizing the mask M will be described with reference to FIG. 7.

FIG. 7 is a pattern diagram illustrating a vapor deposition apparatus 50 that carries out the mask deposition utilizing the described mask M.

The vapor deposition apparatus (the pattern forming apparatus) 50 has a structure having a vapor deposition source 56 at the bottom of a vacuum chamber 52 and the mask M and a glass substrate (the film formation substrate) L at the upper part of the vacuum chamber 52. The mask M and the glass substrate L overlap each other in a manner that the mask M is disposed on the vapor deposition source 56 side (below the glass substrate L) and are supported by support portions 54 connected to the side surfaces of the vacuum chamber 52.

Further, the velocity (vapor deposition velocity) of the vapor deposition material output from the vapor deposition source 56 is controlled by a film thickness sensor 57 such as a quartz resonator, with which a strict control of the film thickness becomes possible.

Furthermore, in order to improve the film thickness distribution of the vapor deposition material, the vapor deposition apparatus 50 may have a structure in which the glass substrate L and the mask M are fixed and revolved together at the time of the vapor deposition process.

Further, there is an electromagnet 60 corresponding to the shape of the mask M above the mask M and the glass substrate L that are mounted on the support portions 54 of the vacuum chamber 52.

The electromagnet 60 attracts the magnetic film 28 arranged on the rear surface MB of the mask M and, thereby, prevents the flexure of the pattern portion 20 of the mask M by its own weight. As shown in FIG. 7, the electromagnet 60 may be a single plate, or there may be a plurality of electromagnets 60, for example, depending on the shape of the pattern of the magnetic film 28. Further, the electromagnet 60 is capable of moving in vertical directions and of stopping at directly above the glass substrate L.

As a specific vapor deposition method (pattern formation method), when the mask M and the glass substrate L are first overlapped and fixed together, the electromagnet 60 moves directly onto the glass substrate L and drives exactly on the glass substrate L so as to generate an electric field. Consequently, the magnetic film 28 on the mask M is attracted to the electromagnet 60, and the pattern portion 20 becomes attached to the glass substrate L.

Thereafter, while driving the electromagnet 60, the vapor deposition material is output from the vapor deposition source 56 to the glass substrate L, passes through the pattern portion 20 of the mask M, and is applied to the glass substrate L. As a consequence, the thin film corresponding to the pattern portion 20 of the mask M is formed on the glass substrate L.

Then, when the film thickness sensor 57 detects that the thickness of the deposited thin film has reached to the desired thickness, a shutter 58 positioned directly above the vapor deposition source 56 is closed, and the vapor deposition process is finished.

Upon finishing the vapor deposition process, the electromagnet 60 stops driving and retrieves upwards. Further, the mask M and the glass substrate L are unfixed, and only the glass substrate L is taken out.

As thus shown, with the vapor deposition apparatus 50, the magnetic film 28 of the mask M is attracted upwards by the magnetic force of the electromagnet 60. Therefore, even when the size of the mask M increases, the flexure of the mask M by its own weight can be avoided, and the mask M can be reliably attached to the glass substrate L. As a consequence, the high-precision pattern can be formed on the glass substrate L.

Additionally, in the embodiment, although the mask M is used as the mask for vapor deposition, it can be used as a mask for sputtering or for CVD. Also, in substitution for the electromagnet 60, the permanent magnet can be used.

Method for Manufacturing Organic EL Device

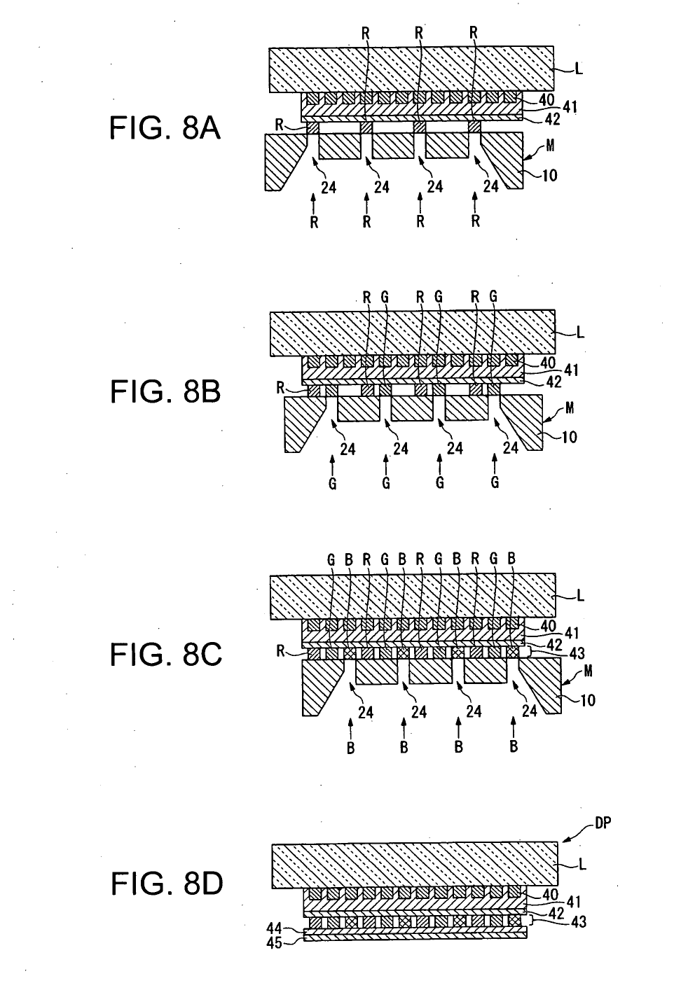

The method for manufacturing the organic EL device using the described mask M is now described with reference to FIGS. 8A through 8D. In this case, materials R, G, and B for forming a light-emitting layer are deposited on the glass substrate L which is the vapor deposition object. In FIGS. 8A through 8D, illustrations of the magnetic film 28 of the mask M are omitted.

At first, as shown in FIG. 8A, a switching element such as a thin film transistor is formed and coupled to anodes 40 provided on the glass substrate L. Also, a hole injection layer 41 and a hole transport layer 42 are formed so as to be coupled to the anodes 40.

Then, while attaching together the mask M and the glass substrate L (the hole transport layer 42), a red light-emitting layer forming material R is deposited on the glass substrate L. The red light-emitting layer forming material R is deposited on the glass substrate L corresponding to the mask apertures 24 of the mask M.

Thereafter, as shown in FIG. 8B, the position of the mask M is shifted from the glass substrate L (alternatively, the mask M is replaced with another mask M), and a green light-emitting layer forming material G is deposited on the glass substrate L in a state that the mask M and the glass substrate L (the hole transport layer 42) are attached together. The green light-emitting layer forming material G is deposited on the glass substrate L corresponding to the mask apertures 24 of the mask M.

Then, as shown in FIG. 8C, the position of the mask M is shifted from the glass substrate L (alternatively, the mask M is replaced with another mask M), and a blue light-emitting layer forming material B is deposited on the glass substrate L in a state that the mask M and the glass substrate L (the hole transport layer 42) are attached together. The blue light-emitting layer forming material B is deposited on the glass substrate L corresponding to the mask apertures 24 of the mask M.

As a result, a light-emitting layer 43 composed of the organic materials of the three colors of R, G, and B is formed on the glass substrate L.

Then, as shown in FIG. 8D, an electron transport layer 44 and a cathode 45 are formed on the light-emitting layer 43 so as to produce an organic EL device DP.

The organic EL device DP of the present embodiment has a configuration in that the light emitted from a light-emitting element containing the light-emitting layer is taken outside the device from the glass substrate L side. The material for forming the glass substrate L may be, in addition to the transparent glass, a transparent or half-transparent material that can transmit the light such as quartz or sapphire, or a transparent synthetic resin such as polyester, polyacrylate, polycarbonate, or polyether ketone. In particular, an inexpensive soda glass may be suitably used as the material for forming the glass substrate L. In contrast, when the organic EL device DP has a configuration in which the emitted-light is taken out from a side opposite from the glass substrate L, the glass substrate L may be nontransparent. In such a case, the material to be used may be ceramic such as alumina, a material like stainless steel obtained when a metal sheet is subjected to an insulating treatment such as surface oxidation, a thermosetting resin, a thermoplastic resin, or the like.

As thus shown, in the method for manufacturing the organic EL device DP of the embodiment, the mask deposition is carried out by using the mask M, and, therefore, each layer formed on the glass substrate L can be precisely arranged. As a consequence, the organic EL device DP that enables the high-precision, vivid image display with no display unevenness can be manufactured.

In addition, the organic EL device DP of the embodiment is an active matrix type, and, in reality, a plurality of data lines and a plurality of scanning lines are arranged in a lattice-like structure. The described light-emitting element is coupled to each of the pixels partitioned by these date lines and the scanning lines and arranged in matrix via driving TFTs such as a switching transistor and a driving transistor. Then, upon supply of a driving signal via the data lines and scanning lines, current flows between the electrodes, and the light-emitting element emits light, which is then output from the outside of a transparent plate to light up the pixels.

Moreover, the invention is not limited to the active matrix type but can certainly be applied to a passive drive type display element.

Electronic Apparatus

Examples of an electronic apparatus equipped with the described organic EL device DP will now be described.

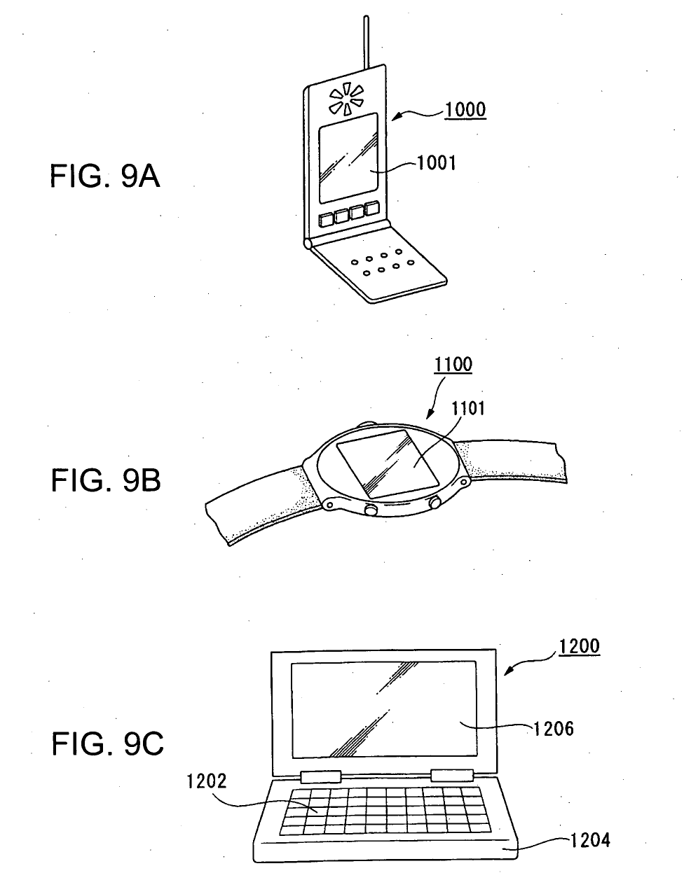

FIG. 9A is a perspective diagram showing an example of a cellular phone. In FIG. 9A, the reference number 1000 indicates a cellular phone body, and the reference number 1001 indicates its display portion using the organic EL device DP.

FIG. 9B is a perspective diagram showing an example of a wristwatch type electronic apparatus. In FIG. 9B, the reference number 1100 indicates a watch body, and the reference number 1101 indicates its display portion using the organic EL device DP.

FIG. 9C is a perspective diagram showing an example of a portable data processing apparatus such as a word processor, a personal computer, or the like. In FIG. 9C, the reference number 1200 indicates a data processing apparatus, 1202 indicates its input portion such as a keyboard, and 1206 indicates its display portion using the organic EL device DP.

Because the electronic apparatuses shown in FIGS. 9A through 9C are equipped with the organic EL device DP of the embodiment in the display portion, they successfully exhibit uniform brightness in the emitted light and display a vivid image with no display unevenness.

Additionally, the electronic apparatus is not limited to the above-referenced cellular phone and the like but may be applied to other various electronic apparatuses, such as a notebook-type computer, a liquid-crystal projector, a personal computer (PC) and an engineering work station (EWS) applicable to multimedia, a pager, a word processor, a television, a view finder type or direct monitor viewing type videotape recorder, an electronic organizer, a desk-top electronic calculator, a car navigation apparatus, a POS terminal, and an apparatus equipped with a touch panel.

What is claimed is:

1. A mask for forming a thin film having a first pattern against a film formation substrate, comprising:
a nonmagnetic substrate having an aperture corresponding to the first pattern; and
a magnetic film having a second pattern and arranged on the nonmagnetic substrate.

2. The mask according to claim 1, wherein the magnetic film is arranged on a surface of the nonmagnetic substrate opposite from the film formation substrate.

3. The mask according to claim 1, wherein the magnetic film is arranged in a central region of the opposite surface.

4. The mask according to claim 1, wherein the magnetic film has a thickness of from 0.5 μm to 5.0 μm.

5. A mask manufacturing method for forming a thin film having a first pattern against a film formation substrate, comprising:
forming an aperture corresponding to the first pattern against a nonmagnetic substrate; and
arranging a magnetic film having a second pattern on the nonmagnetic substrate.

6. The mask manufacturing method according to claim 5, wherein the magnetic film arrangement process includes:
first forming a base metal film corresponding to the second pattern on the predetermined surface; and
secondly forming the magnetic film on the base metal film.

7. The mask manufacturing method according to claim 6, wherein the second magnetic film formation process includes depositing the magnetic film on the base metal film by an electroless plating method.

8. A pattern forming apparatus, comprising:
support portions supporting the mask and the film formation substrate of claim 1 from opposite directions in a manner that the film formation substrate comes vertically above the mask;
a magnetic attraction portion which is arranged vertically above the film formation substrate and which applies a magnetic attraction force to the mask to attract the mask towards the film formation substrate; and
a film formation portion at which a thin film formation material is applied to the film formation substrate via the mask.

9. A pattern formation method, comprising:
arranging the mask and the film formation substrate of claim 1 so that they oppose each other and that the film formation substrate comes vertically above the mask;
applying a magnetic attraction force to the mask to attract the mask towards the film formation substrate; and
applying a thin film formation material to the film formation substrate via the mask.
